(19) United States
(12) Patent Application Publication
(10) Pub. No.: US 2024/0072412 A1
(43) Pub. Date: Feb. 29, 2024

(54) DISPLAY DEVICE

(71) Applicant: Japan Display Inc., Tokyo (JP)

(72) Inventor: Kenji HARADA, Tokyo (JP)

(21) Appl. No.: 18/451,149

(22) Filed: Aug. 17, 2023

(30) Foreign Application Priority Data
Aug. 24, 2022 (JP) 2022-133067

(51) Int. Cl. H01Q 1/22; G06F 3/041; G06F 3/044; H01Q 1/38; H10K 59/40

(52) U.S. Cl. CPC H01Q 1/22; G06F 3/0412; G06F 3/04164; G06F 3/0443; G06F 3/0446; H01Q 1/38; H10K 59/40

(57) ABSTRACT

A touch sensor built-in display device having a near field communication function includes a display panel providing a display function, a touch electrode for the touch sensor formed in a layer disposed on a display surface side of the display panel, and an antenna wire for a near field communication function formed in a same layer as the touch electrode.

### CROSS-REFERENCE TO RELATED APPLICATION

The present application claims priority from Japanese application JP 2022-133067 filed on Aug. 24, 2022, the content of which is hereby incorporated by reference into this application.

### BACKGROUND OF THE INVENTION

### 1. Field of the Invention

The present invention relates to a display device.

### 2. Description of the Related Art

U.S. patent Ser. No. 10/436,963 discloses that an antenna-integrated polarizer is provided on a display device so that the display device including an antenna can increase the reception area of the antenna and to minimize folding-resistant force.

Further, “Integrated Transparent NFC Antennas on Touch Displays” by Yasuhiro Sugita, Jean Mugiraneza, Shinji Yamagishi, ITE Transactions on Media Technology and Applications, 2018, discloses a technology for integrating a touch display and an antenna for NFC (Near Field Communication), in which a layer formed by integrating a touch panel and an antenna into one body is combined with a display module separately configured.

The drawings disclosed in U.S. patent Ser. No. 10/436,963 and the Non-Patent Literature described above show a layer where an antenna is formed is located between a layer of a touch panel and a layer of a display panel. For performing near field communication with such a device, the display surface of the device is typically directed to oppose the communication target. However, in the case where the antenna is placed as described above, the antenna performs communication via the layer of the touch panel, and thus the layer of the touch panel may inhibit communication.

### SUMMARY OF THE INVENTION

One or more embodiments of the present invention have been conceived in view of the above, and an object thereof is to improve accuracy of communication in a display device including a touch sensor and a near field communication antenna.

### Solution to Problem

In order to solve the above described problems, an aspect of the present invention is a touch sensor built-in display device that includes a near field communication function and a display panel providing a display function, a touch electrode included in a touch sensor that is formed in a layer disposed on a display surface side of the display panel, and an antenna wire for a near field communication function formed in a same layer as the touch electrode.

### BRIEF DESCRIPTION OF THE DRAWINGS

FIG. 1 is a diagram illustrating an example of a device including a touch display with an antenna according to the present invention;

FIG. 2 is a diagram illustrating layers constituting the touch display with an antenna according to the present invention;

FIG. 3 is a diagram illustrating aspects of near field communication performed by the device including the touch display with an antenna according to the present invention;

FIG. 4 is a plan view of the device including the touch display with an antenna according to the first embodiment of the present invention;

FIG. 5 is a plan view of the device including the touch display with an antenna according to the first embodiment of the present invention;

FIG. 6 is a cross-sectional view taken along the line I-I shown in FIG. 4;

FIG. 7 is a cross-sectional view taken along the line II-II shown in FIG. 4;

FIG. 8 is a cross-sectional view taken along the line III-III shown in FIG. 4;

FIG. 9 is a cross-sectional view taken along the line IV-IV shown in FIG. 5;

FIG. 10 is a plan view of the device including the touch display with an antenna according to the second embodiment of the present invention;

FIG. 11 is a cross-sectional view taken along the line I-I shown in FIG. 10;

FIG. 12 is a cross-sectional view taken along the line II-II shown in FIG. 10;

FIG. 13 is a cross-sectional view taken along the line III-III shown in FIG. 10;

FIG. 14 is a plan view of the device including the touch display with an antenna according to the third embodiment of the present invention;

FIG. 15 is a cross-sectional view taken along the line I-I shown in FIG. 14;

FIG. 16 is a cross-sectional view taken along the line II-II shown in FIG. 14;

FIG. 17 is a plan view of the device including the touch display with an antenna according to the fourth embodiment of the present invention;

FIG. 18 is a plan view of the device including the touch display with an antenna according to the fourth embodiment of the present invention;

FIG. 19 is a plan view of the device including the touch display with an antenna according to the fifth embodiment of the present invention; and

FIG. 20 is a plan view of the device including the touch display with an antenna according to the fifth embodiment of the present invention.

### DETAILED DESCRIPTION OF THE INVENTION

Embodiments of the present invention will be described below referring to the drawings. The disclosure is merely an example, and appropriate modifications while keeping the gist of the invention that can be easily conceived by those skilled in the art are naturally included in the scope of the invention. The accompanying drawings may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

Further, in the detailed description of the embodiments of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

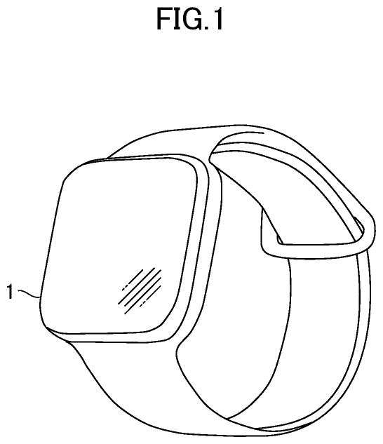

FIG. 1 is a diagram illustrating an example of a device on which a touch sensor built-in display device 1 according to the present embodiment is mounted. As shown in FIG. 1, the touch sensor built-in display device according to the present embodiment is particularly effective when mounted on a wearable terminal, such as a smart watch.

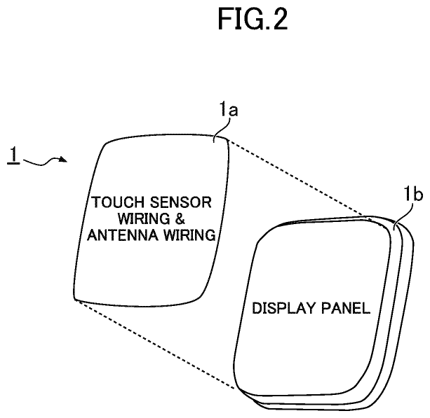

FIG. 2 is a diagram showing a general configuration of the touch sensor built-in display device 1 according to the present embodiment. The touch sensor built-in display device 1 according to the present embodiment is roughly divided into a sensor antenna layer 1a including touch sensor wiring and antenna wiring, and a display panel 1b providing display functions. As shown in FIG. 2, the sensor antenna layer 1a is formed on the display surface side of the display panel 1b.

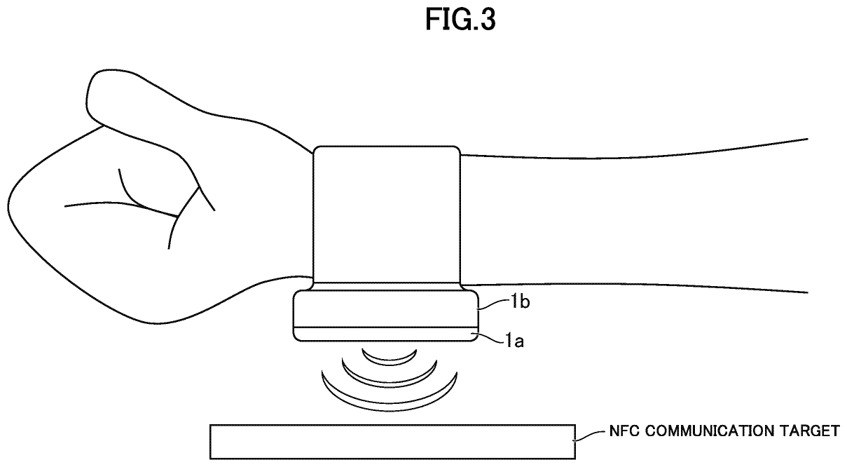

FIG. 3 is a diagram showing a state when a smartwatch equipped with the touch sensor built-in display device 1 according to the present embodiment performs near field communication.

As shown in FIG. 3, when performing communication using a near field communication function mounted on a smart watch, the display surface is typically directed to oppose the communication target to be closer to the target. In such a situation, as shown in FIG. 3, the sensor antenna layer 1a formed on the display surface side of the display panel 1b is brought closest to the communication target. As such, communication radio waves from the sensor antenna layer 1a are not blocked by other parts of the smartwatch including the display panel 1b, and the communication accuracy can be thereby improved.

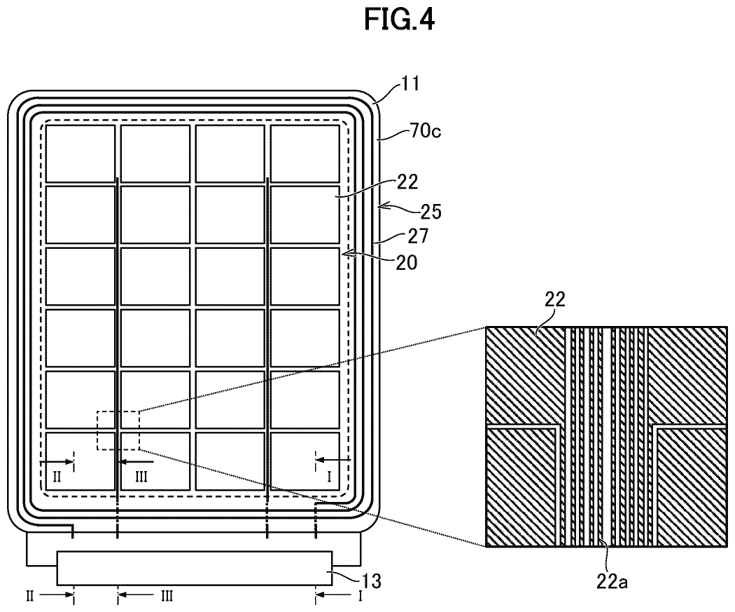

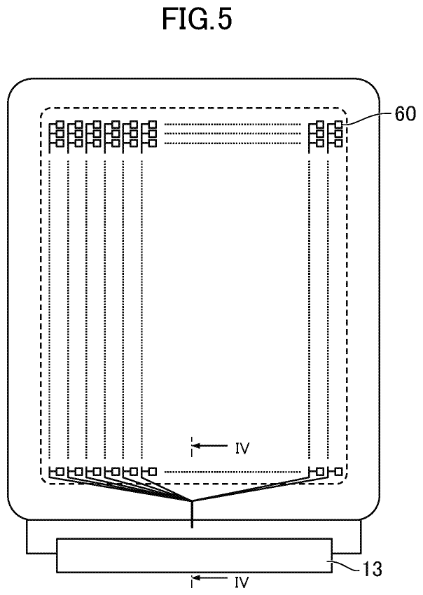

FIGS. 4 and 5 are plan views of the touch sensor built-in display device 1 according to the present embodiment. FIG. 4 shows the sensor antenna layer 1a, and FIG. 5 shows a configuration of the display panel 1b. An organic EL display device is taken as an example of the display panel 1b. The display panel 1b forms full-color pixels of a combination of unit pixels (sub-pixels) in a plurality of colors, such as red, green, and blue, to display a full-color image.

A peripheral area (frame area) 11 is formed outside the display area of the display panel 1b indicated by broken lines in FIGS. 4 and 5, and an FPC 13 for electrical connection to the outside is connected to one side (lower side in FIGS. 4 and 5) of the peripheral area 11. Further, an antenna 25 for near field communication is formed in the peripheral area 11. The antenna 25 is shaped in a large coil so that the antenna wire 27 surrounds the display area in the peripheral area 11 that surrounds the periphery of the display area. In the present embodiment, as shown in FIG. 4, the antenna wire 27 is formed along the peripheral area starting from one end (left side in FIG. 4) of the side of the peripheral area to which the FPC 13 is connected (hereinafter, connection side), is coiled almost in threefold, and ends at the other end (right side in FIG. 4) of the connection side, thereby forming the antenna 25. This is an example and the coil may be twofold or less or fourfold or more. In the following, a direction along the connection side to which the FPC 13 is connected is referred to as an X direction, and a direction perpendicular to the X direction is referred to as a Y direction.

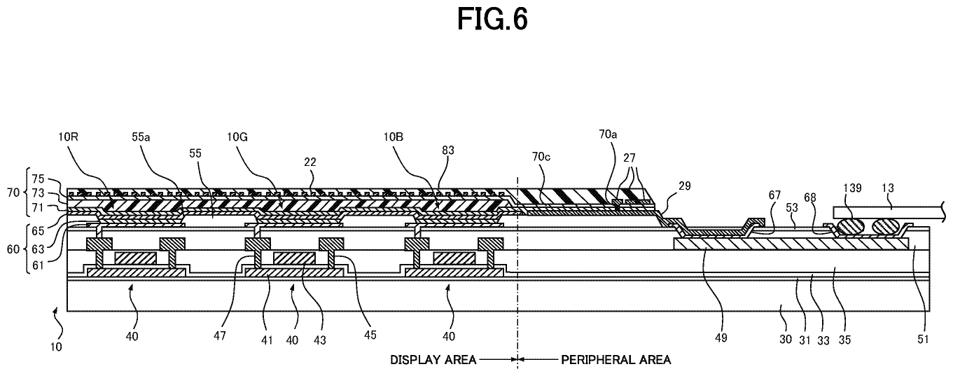

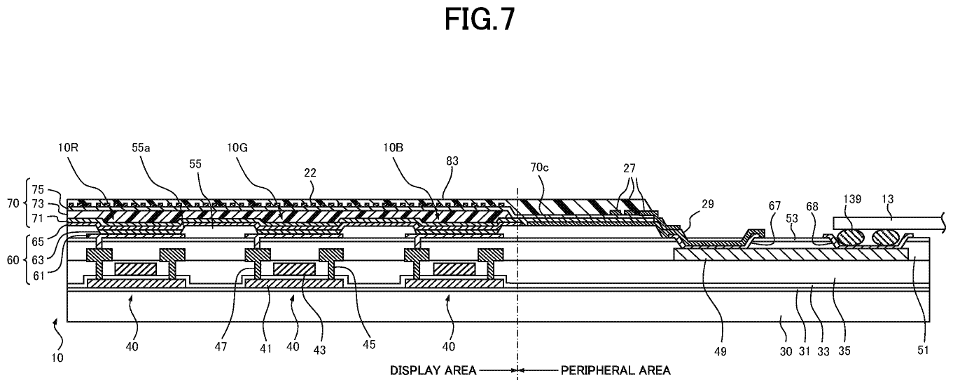

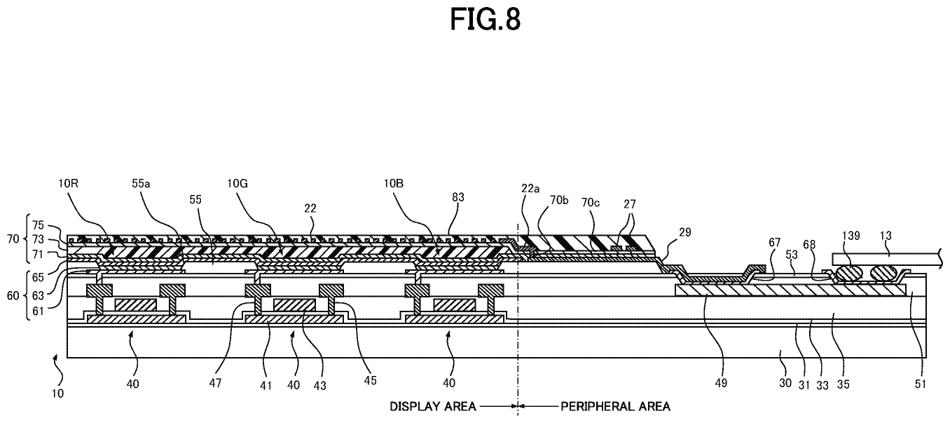

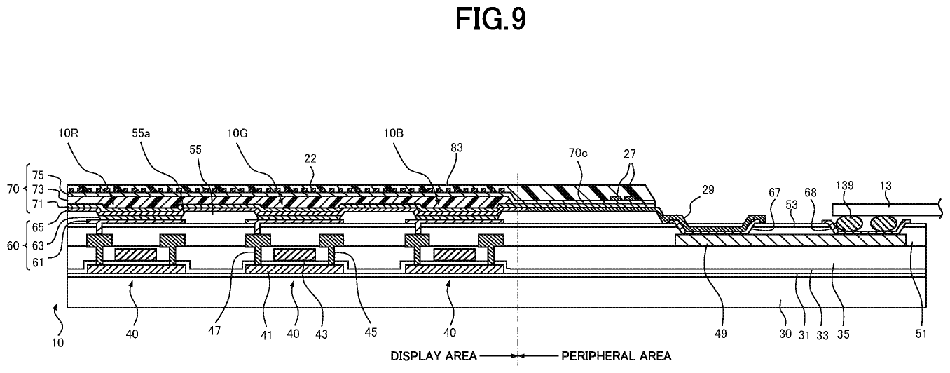

FIG. 6 is a cross-sectional view taken along the line I-I shown in FIG. 4. FIG. 7 is a cross-sectional view taken along the line II-II shown in FIG. 4. FIG. 8 is a cross-sectional view taken along the line III-III shown in FIG. 4. FIG. 9 is a cross-sectional view taken along the line IV-IV shown in FIG. 5. In FIGS. 6 to 9, hatching of some layers, such as a substrate 30, a flattening film 51, and an interlayer insulating film 53, is omitted for clarity of the cross-sectional structure. In the following, the lamination direction is an upward direction.

The substrate 30 is made of glass or a flexible resin, such as polyimide. The upper surface of the substrate 30 is covered with an undercoat layer 31. A semiconductor layer 41 is formed on the undercoat layer 31, and the semiconductor layer 41 is covered with a gate insulating film 33. A gate electrode 43 is formed on the gate insulating film 33, and the gate electrode 43 is covered with a passivation film 35. A drain electrode 45 and a source electrode 47 are connected to the semiconductor layer 41 through the gate insulating film 33 and the passivation film 35. The semiconductor layer 41, the gate electrode 43, the drain electrode 45, and the source electrode 47 constitute a thin film transistor 40. The thin film transistor 40 is provided so as to correspond to each of the unit pixels. The undercoat layer 31, the gate insulating film 33, and the passivation film 35 are formed of an inorganic insulating material, such as SiO₂ and SiN.

On the passivation film 35, a lead wire 49 is formed in the peripheral area 11 in addition to the drain electrode 45 and the source electrode 47. The lead wire 49 electrically connects the touch sensor 20 and the antennae 25 to the FPC 13. The drain electrode 45, the source electrode 47, and the lead wire 49 are covered with the flattening film 51, and the flattening film 51 is covered with the interlayer insulating film 53. The drain electrode 45, the source electrode 47, and the lead wire 49 are formed of a conductive material including Al, Ag, Cu, Ni, Ti, and Mo, for example. The flattening film 51 is formed of an organic insulating material, such as an acrylic resin, and has a flat upper surface. The interlayer insulating film 53 is formed of an inorganic insulating material, such as SiO₂ and SiN.

A pixel electrode 61 (e.g., anode) is formed on the interlayer insulating film 53. The pixel electrode 61 is connected to the source electrode 47 through the flattening film 51 and the interlayer insulating film 53. The pixel electrode 61 is provided so as to correspond to each of the unit pixels. The pixel electrode 61 is formed as a reflective electrode. Terminals 67 and 68 are formed in the peripheral area 11 and are connected to both ends of the lead wire 49 through the flattening film 51 and the interlayer insulating film 53. The pixel electrode 61 and the terminals 67 and 68 are formed of a conductive material including Al, Ag, Cu, Ni, Ti, and Mo, for example, or a conductive oxide, such as ITO and IZO.

The pixel electrode 61 is covered with the pixel separation film 55. The pixel separation film 55 is also referred to as a rib or a bank. The pixel separation film 55 has an opening 55a in which the pixel electrode 61 is exposed in the bottom. The inner edge portion of the pixel separation film 55 forming the opening 55a is provided on the peripheral edge portion of the pixel electrode 61, and has an inverted tapered shape that spreads outward as it extends upward. The pixel separation film 55 is not formed in the peripheral area 11. The pixel separation film 55 is formed of an organic material, such as an acrylic resin and a polyimide resin.

Light emitting layers 63 is formed apart from each other on the pixel electrode 61 exposed at the bottom of the opening 55a of the pixel separation film 55. The light emitting layers 63 emit light in a plurality of colors including red, green, and blue, for example, in corresponding to each of the unit pixels. At least one of a hole transport layer, a hole injection layer, an electron transport layer, and an electron injection layer may be formed together with the light emitting layers 63. The light emitting layers 63 are individually deposited and formed using a mask. The light emitting layer 63 may be formed by vapor deposition as a uniform film (so-called solid film) extending over a plurality of unit pixels and over the entire display area. In this case, the light emitting layer 63 emits white light, and each component of a plurality of colors including red, green, and blue is extracted by a color filter, for example. The light emitting layer 63 is not limited to be formed by vapor deposition, and may be formed by coating.

The light emitting layer 63 and the pixel separation film 55 are covered with a counter electrode 65 (e.g., cathode). The counter electrode 65 is formed as a uniform film (so-called solid film) extending over a plurality of unit pixels and over the entire display area. A light emitting element 60 includes the pixel electrode 61, the counter electrode 65, and the light emitting layer 63 disposed therebetween, and the light emitting layer 63 emits light by a current flowing between the pixel electrode 61 and the counter electrode 65. The counter electrode 65 is formed of a transparent conductive material, such as ITO, or a metallic thin film, such as MgAg.

The pixel separation film 55 and the counter electrode 65 are covered by a sealing film (passivation film) 70 and thus sealed, thereby being blocked from moisture. The sealing film 70 has a three-layer lamination structure including, for example, an inorganic film 71, an organic film 73, and an inorganic film 75 in this order from the bottom. The inorganic films 71 and 75 are outer layers of the three-layer lamination structure, and are formed of an inorganic insulating material, such as SiO₂ and SiN. The organic film 73 is an intermediate layer of the three-layer lamination structure, and is formed of an organic insulating material, such as an acrylic resin, and flattens the upper surface of the sealing film 70. As shown in FIG. 4, the wiring for the touch sensor 20 and the antenna wire 27 for the antenna 25 are formed on the sealing film 70, and this is one of the embodiments of the present invention.

The sealing film 70 is formed to include the organic film 73 between the inorganic film 71 and the inorganic film 75 so that the organic film 73 is not exposed to the outside air. The organic film 73 is securely put between the inorganic film 71 and the inorganic film 75, and thus the organic film 73 does not exist in the part of the outer periphery of the area where the organic film 73 is put between the inorganic film 71 and the inorganic film 75, which are bonded together there. This part is a margin portion 70c surrounding the inner organic film 73 on the sealing film 70. The margin portion 70c is positioned in the peripheral area 11 on the plane of the display panel. The wiring for the antenna 25 is formed on the margin portion 70c, and an opening for crossing the wiring for the touch sensor 20 and the antenna wire 27 is also provided on the margin portion 70c. The sealing film 70 is not formed on the terminals 67 and 68.

The touch sensor built-in display device 1 according to the present embodiment includes the touch sensor 20 on the sealing film 70. In the present embodiment, the touch sensor 20 is illustrated as being directly formed on the sealing film 70, but may be formed via a base insulating film. The base insulating film may use an organic insulating material, such as an acrylic resin, and flattens the upper surface. As shown in FIG. 4, the touch sensor 20 is constituted by touch electrodes 22 respectively covering the areas, which are the display area divided into a plurality of areas, and being formed on the sealing film 70.

The touch electrode 22 is an electrode of a capacitive touch sensor, and when a finger of a person approaches the touch electrode 22, the fingertip and the touch electrode 22 act as a capacitor to generate a capacitance. When the IC connected to the touch electrode 22 detects the capacitance, the touch electrode 22 functions as a touch sensor. The touch electrode 22 is covered with a surface insulating film 83. The surface insulating film 83 is formed of an inorganic insulating material, such as SiO₂ and SiN, or an organic insulating material, such as acryl resin.

FIG. 4 shows the touch electrode 22 as a planar electrode that covers each area obtained by dividing the display area into a plurality of areas, although is actually formed of a mesh wire made of a conductive material, such as metal. As such, in each of the cross-sectional views including FIG. 6, the touch electrode 22 is illustrated as corresponding to a mesh. The touch electrode 22 is formed of a conductive material including Al, Ag, Cu, Ni, Ti, and Mo, for example. In the touch electrode 22 formed in a mesh shape, the area of the opening of the mesh is sufficiently wide relative to the area occupied by the wiring portion with respect to the display surface, and thus light emitted by the light-emitting element reaches the observer sufficiently through the opening of the mesh. As such, the observer can visually recognize the display surface without being conscious of the mesh wire. Alternatively, the touch electrode 22 may be formed of a transparent conductive film.

As can be seen in an enlarged view of FIG. 4, a touch wire 22a is led out from each touch electrode 22, and is formed individually toward the connection side. In order to bring the touch wire 22a to conduct to the FPC 13, the sealing film 70 includes a configuration for avoiding the antenna wire 27 formed on the same layer.

A lead wire 29 is formed in a peripheral edge portion of the surface insulating film 83. The lead wire 29 leads out the touch electrode 22 the antenna wire 27 formed on the sealing film 70 and the counter electrode 65 of the light emitting element 60, and connects them to the corresponding terminals 67. The lead wire 29 is formed in a layer between the flattening film 51 and the sealing film 70 in the peripheral area 11, and extends beyond the edges of the surface insulating film 83 and the sealing film 70 to the area embedded with the outer lead wire 49.

Among two terminals 67 and 68 connected to the lead wire 49, the lead wire 29 is connected to a terminal 67 formed on a side close to the touch sensor 20. On the other hand, the FPC13 is connected to the terminal 68 away from the touch sensor 20 via an anisotropic conductive member 139. As described above, the terminal (touch terminal) connected from the touch electrode 22 via the touch wire 22a, the terminal (display terminal) for driving the light emitting element 60 providing the display functions, and the terminal (antenna terminal) for driving the antenna wire 27 constituting the antenna 25 are all collected on the connection side, and constitute a terminal group on the connection side as the corresponding terminals 68. When the FPC 13 is connected to the terminal group, the touch sensor built-in display device 1 is driven.

The touch electrode 22 and the antenna wire 27 are formed in the same layer as shown in FIGS. 4 and 6. Despite that, the antenna wire 27 is coiled using the peripheral area 11, and thus the touch electrode 22 and the inner coil end of the antenna wire 27 are blocked by the coiled antenna wire 27 and cannot be led to the outside. In contrast, in the present embodiment, the wire is made conductive to the other layers through the opening (through hole) formed in the margin portion 70c of the sealing film 70, thereby ensuring the conduction between the wires inside the coil and the outside (particularly, FPC13) to solve this problem.

FIG. 6 shows conduction between the inner coil end of the coiled antenna wire 27 and the outside. As shown in FIG. 6, the inner coil end of the antenna wire 27 is connected to the lead wire 29 through an opening 70a formed in the margin portion 70c of the sealing film 70. The conduction by the lead wire 29 is indicated by a broken line at the position of the cutting line I-I in FIG. 4. This ensures conduction between the inner end of the antenna wire 27 and the outside through the lead wire 29 that intersects the antenna wire 27 via the margin portion 70c of the sealing film 70.

FIG. 7 shows conduction between the outer coil end of the coiled antenna wire 27 and the outside. As shown in FIG. 7, the outer coil end of the antenna wire 27 is wired outward beyond the margin portion 70c of the sealing film 70 to be connected to the lead wire 29.

FIG. 8 shows conduction between the touch wire 22a, which is led out from the touch electrode 22, and the outside. As shown in FIG. 8, the touch wire 22a is connected to the lead wire 29 through an opening 70b formed in the margin portion 70c of the sealing film 70. The conduction by the lead wire 29 is indicated by a broken line at the position of the cutting line III-III in FIG. 4. This ensures conduction between the touch wire 22a and the outside through the lead wire 29 that intersects the antenna wire 27 via the margin portion 70c of the sealing film 70.

FIG. 9 shows conduction between the counter electrode 65 of the light emitting element 60 and the outside. As shown in FIG. 9, the counter electrode 65 is connected to the lead wire 29 in the layer underlying the sealing film 70. This ensures conduction between the counter electrode 65 and the outside through the lead wire 29 that intersects the antenna wire 27 via the margin portion 70c of the sealing film 70.

As in the present embodiment, the antenna wire 27 is patterned on the sealing film 70 in the same layer as the touch electrode 22, and thus, the communication radio waves from the antenna 25 is not blocked by the touch electrode 22 or other components. This improves accuracy in communication by the antenna 25. Further, the antenna wire 27 and the touch electrode 22 are formed on the same layer, and this eliminates the need of separately providing a member serving as a substrate for patterning the antenna wire 27 as in the conventional art, thereby reducing the size and material cost.

In the present embodiment, the touch electrode 22 is made conductive to the other layer through the opening 70b of the sealing film 70 so that the touch electrode 22, which is in the same layer as the coiled antenna wire 27 and is formed inside the coil, is conducted to the FPC 13 arranged outward of the coil. At this time, the opening 70b is formed on the margin 70c where the inorganic film 71 and the inorganic film 75 are bonded together in the sealing film 70, and thus the organic film 73 inside is sealed by the inorganic film 71 and the inorganic film 75. This prevents degradation of the organic film 73. The sealing film 70 is used for an organic EL display device, and the present embodiment is particularly effective when applied to the organic EL display device.

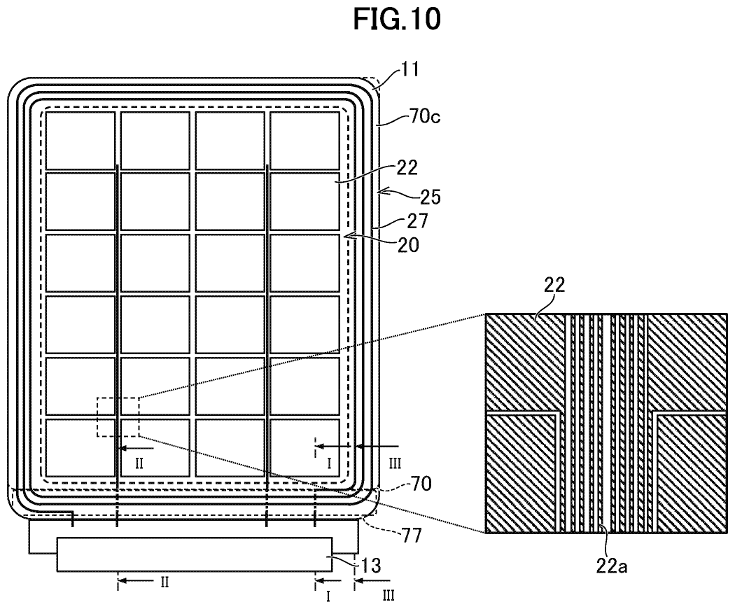

FIG. 10 is a plan view of the touch sensor built-in display device 1 according to the second embodiment, and shows the sensor antenna layer 1a. In the second embodiment, an insulating film 77 provided separately from the sealing film 70 serves as the margin portion 70c in the first embodiment. This provides the same effects as those of the first embodiment.

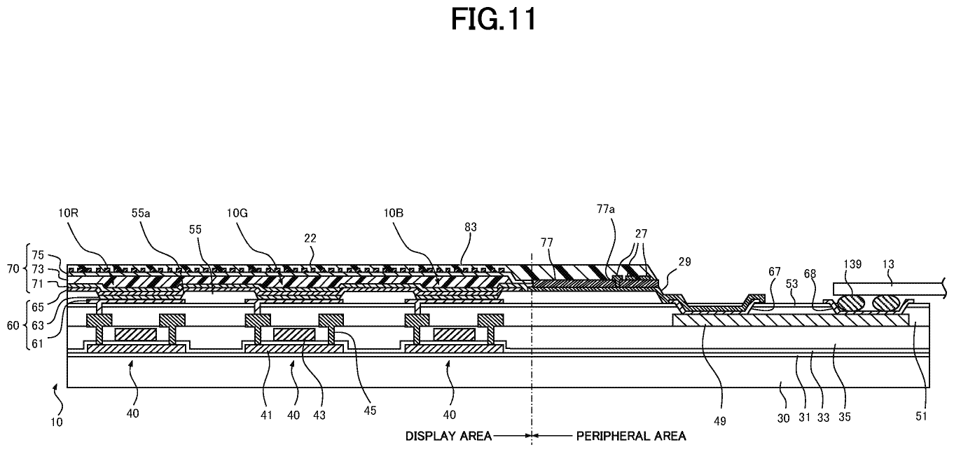

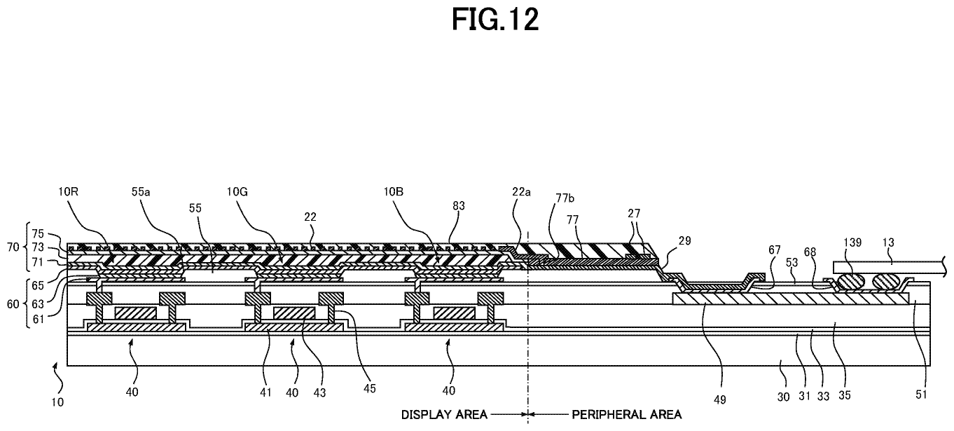

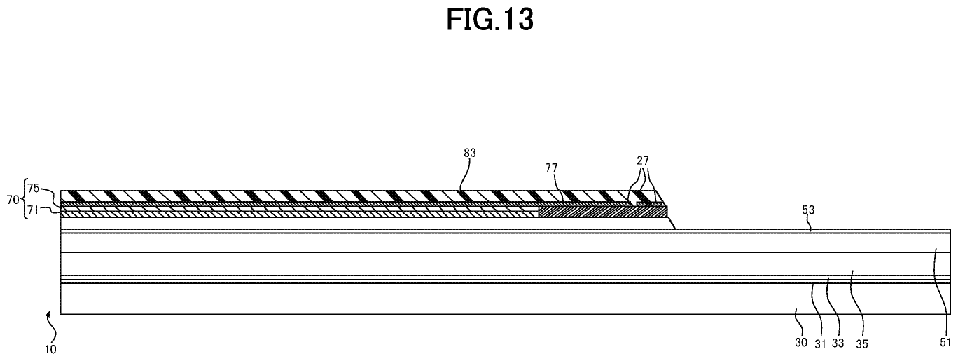

FIG. 11 is a cross-sectional view taken along the line I-I shown in FIG. 10. FIG. 12 is a cross-sectional view taken along the line II-II shown in FIG. 10. FIG. 13 is a cross-sectional view taken along the line III-III shown in FIG. 10. As shown in FIGS. 11 to 13, the length of the portion where the inorganic film 71 and the inorganic film 75 constituting the sealing film 70 according to the present embodiment are bonded together is minimally short, and the insulating film 77 is provided instead of the margin part 70c of the first embodiment. As in the first embodiment, the antenna wire 27 is patterned in the peripheral area 11 on the sealing film 70, which is the same layer as the touch electrode 22, but is patterned on the insulating film 77 on the connection side of the peripheral area 11.

FIG. 11 shows conduction between the inner coil end of the coiled antenna wire 27 and the outside. As shown in FIG. 11, the inner coil end of the antenna wire 27 is connected to the lead wire 29 through an opening 77a formed in the insulating film 77. The conduction by the lead wire 29 is indicated by a broken line at the position of the line I-I in FIG. 10. This ensures conduction between the inner end portion of the antenna wire 27 and the outside through the lead wire 29 that intersects the antenna wire 27 via the insulating film 77.

FIG. 12 shows conduction between the touch wire 22a and the outside. As shown in FIG. 12, the touch wire 22a led out in the peripheral area 11 side is connected to the lead wire 29 through an opening 77b formed in the insulating film 77. The conduction by the lead wire 29 is indicated by a broken line at the position of the line II-II in FIG. 10. This ensures conduction between the touch wire 22a and the outside through the lead wire 29 that intersects the antenna wire 27 via the insulating film 77.

FIG. 13 shows the antenna wire 27 formed over the sealing film 70 and the insulating film 77. As described above, the antenna wire 27 is also formed on the sealing film 70, which is the same layer as the touch electrode 22, in the present embodiment, although the antenna wire 27 is formed on the insulating film 77 only on the connection side.

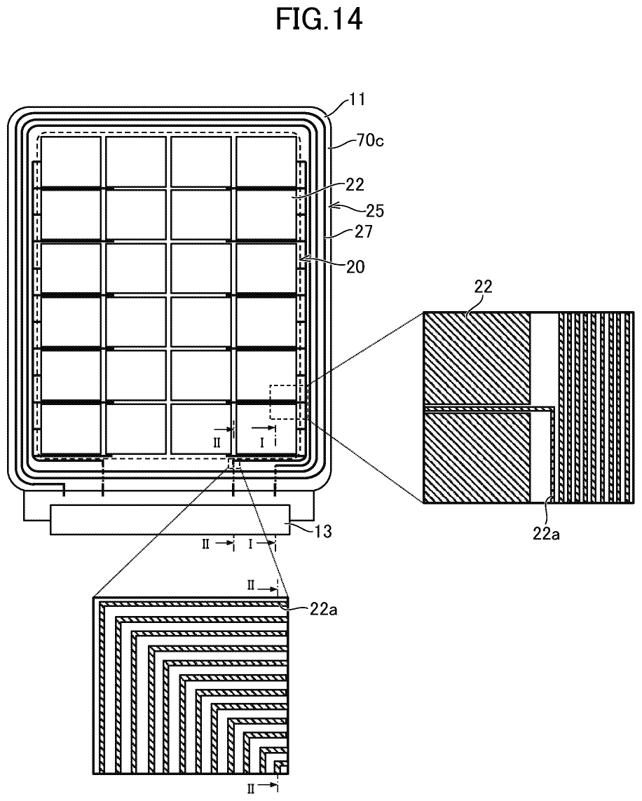

FIG. 14 is a plan view of the touch sensor built-in display device 1 according to the third embodiment, and shows the sensor antenna layer 1a. In the third embodiment, the touch wire 22a that connects the touch electrodes 22 of the touch sensor 20 with the FPC 13 is not directly wired from the display area to the connection side, but is guided to both sides perpendicular to the connection side and formed to the connection side through the peripheral area 11 on each side. This also provides the same effects as those of the first embodiment. The first embodiment and the third embodiment are selected in accordance with the configuration of the device on which the touch sensor built-in display device 1 is mounted and the restrictions of wiring.

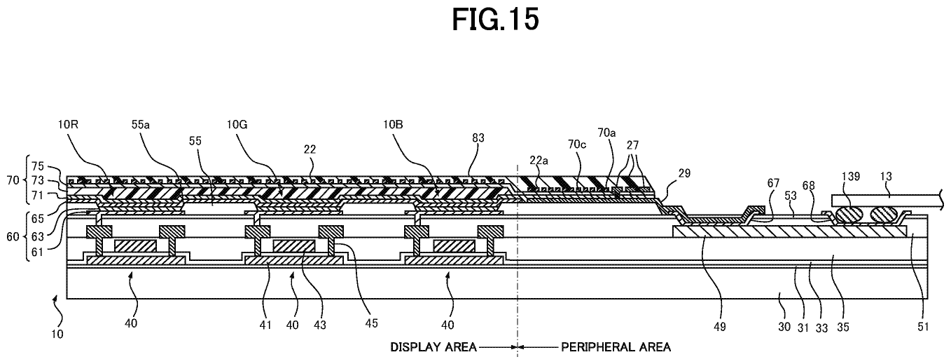

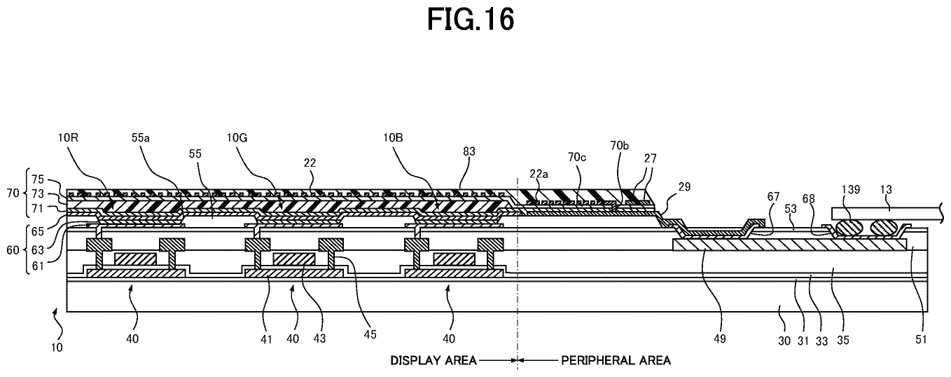

FIG. 15 is a cross-sectional view taken along the line I-I shown in FIG. 14. FIG. 16 is a cross-sectional view taken along the line II-II shown in FIG. 14. As enlarged and displayed in FIG. 14, at most twelve touch wires 22a of the touch electrodes 22 are arranged in each of the peripheral areas 11 on both sides. As shown in FIGS. 15 and 16, twelve touch wires 22a are arranged on both left and right sides of the peripheral area 11 on the connection side.

FIG. 15 shows conduction between the inner coil end of the coiled antenna wire 27 and the outside. As shown in FIG. 15, the inner coil end of the antenna wire 27 is connected to the lead wire 29 through an opening 70a formed in the margin portion 70c of the sealing film 70. The conduction by the lead wire 29 is indicated by a broken line at the position of the cutting line I-I in FIG. 14. This ensures conduction between the inner end of the antenna wire 27 and the outside through the lead wire 29 that intersects the antenna wire 27 via the margin portion 70c of the sealing film 70.

FIG. 16 shows conduction between the outermost touch wire 22a (disposed on the FPC 13 side) and the outside. As shown in FIG. 16, the touch electrode 22 is connected to the lead wire 29 through an opening 70b formed in the margin portion 70c of the sealing film 70. The conduction by the lead wire 29 is indicated by a broken line at the position of the cutting line II-II in FIG. 16. This ensures conduction between the touch wire 22a and the outside through the lead wire 29 that intersects the antenna wire 27 via the margin portion 70c of the sealing film 70.

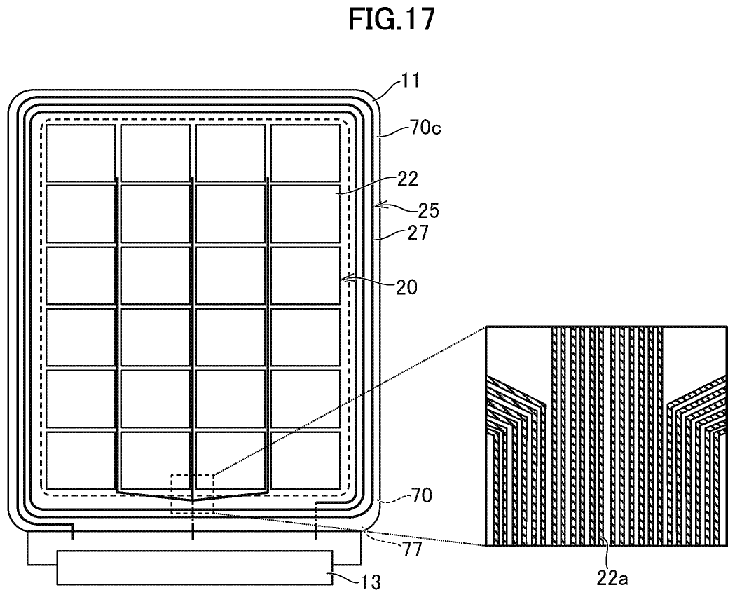

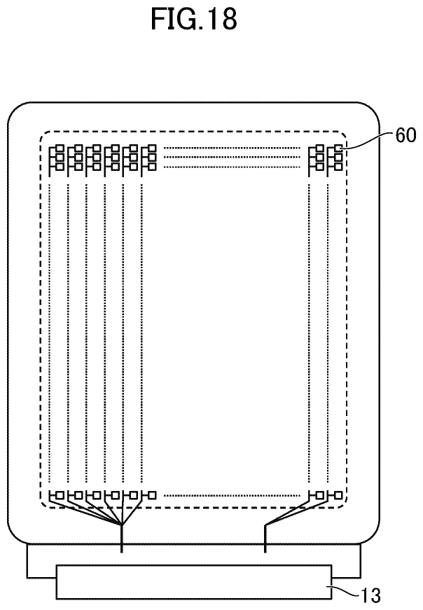

FIG. 17 and FIG. 18 are plan views of the touch sensor built-in display device 1 according to the fourth embodiment. FIG. 17 shows a sensor antenna layer 1a, and FIG. 18 shows a display panel 1b. The touch sensor built-in display device 1 according to the fourth embodiment differs from that in the first embodiment in wiring of the touch wire 22a and the display panel 1b. This also provides the same effects as those of the first embodiment. The first embodiment and the fourth embodiment are selected in accordance with the configuration of the device on which the touch sensor built-in display device 1 is mounted and the restrictions of wiring.

In the first embodiment, as shown in FIG. 4, the touch electrodes 22 arranged in four columns×six rows are divided into the right two columns and the left two columns. The touch wires of the left group are collected between the first column and the second column, and the touch wires of the right group are collected between the third column and the fourth column, and guided to the connection side. In the fourth embodiment, as shown in FIG. 17, the touch wires 22a are led out between the columns, and are collected between the second column and the third column, that is, in the center in the X-direction, and are guided to the connection side.

In the first embodiment, as shown in FIG. 5, the wires of the light emitting device 60 are guided to the connection side for each column, and then collected in the center in the X-direction and guided to the connection side so as to avoid the position of the touch wires 22a. In this regard, in the fourth embodiment, as shown in FIG. 18, the wires of the light emitting device are guided to the connection side for each column, and then collected in both sides and guided to the connection side so as to avoid the touch wires 22a collected in the center in the X-direction. As indicated by the broken line in FIG. 17, the fourth embodiment also has the configuration in which the touch wires 22a and the inner coil end of the antenna wire 27 are guided to the lead wire 29 through the openings 70a and 70b provided in the sealing film 70 and are led out of the coil.

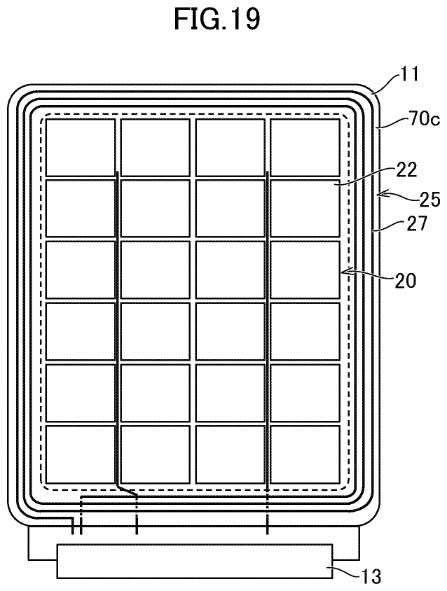

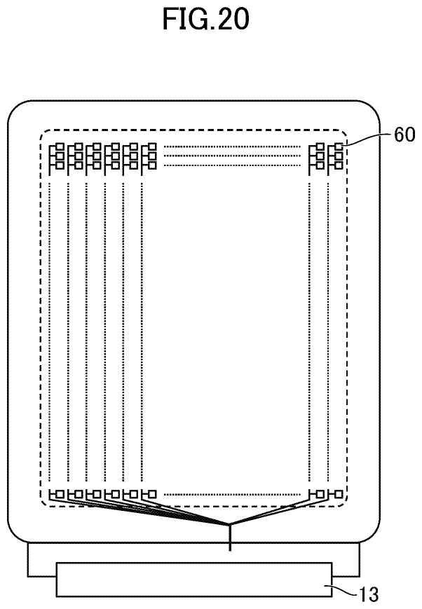

FIGS. 19 and 20 are plan views of the touch sensor built-in display device 1 according to the fifth embodiment. FIG. 19 shows a sensor antenna layer 1a, and FIG. 20 shows a display panel 1b. The touch sensor built-in display device 1 according to the fifth embodiment is different from that in the first embodiment in the arrangement of the antenna wire 27 to increase the number of coil turns of the antenna 25 to improve the antenna sensitivity.

In the first embodiment, as shown in FIG. 4, one end of the coil of the antenna wire 27 is disposed at the left end of the connection side, and the other end of the coil is disposed at the right end on the connection side. In this manner, the number of turns of the antenna 25 is “three” for the most part, but the number of turns is partially “two” in the range along the connection side.

In this regard, in the fifth embodiment, as shown in FIG. 19, both ends of the coil of the antenna wire 27 are disposed adjacent to each other in the left end of the connection side. As such, the terminal 68 (first coil terminal) corresponding to one end of the coil of the antenna wire 27 and the terminal 68 (second coil terminal) corresponding to the other end of the coil are disposed adjacent to each other. Accordingly, the number of turns of the antenna 25 is “three” as a whole. This serves to improve the antenna sensitivity as compared with the first embodiment. Further, the coil ends of the antenna wire 27 are collected on the left side as shown in FIG. 19 and FIG. 20, the positions where the wiring of the touch wires 22a and the light emitting device 60 is guided to the connection side are adjusted.

In the fifth embodiment, both ends of the coil of the antenna wire 27 are disposed at the left end on the connection side in the drawings, although the same effect can be obtained on the right side if both ends of the coil are disposed adjacent to each other. In this case, the positions where the wiring of the touch wire 22a and the light emitting elements 60 are guided to the connection sides are adjusted in the same manner.

In the embodiment described above, the case has been described in which the touch sensor 20 includes the touch electrode 22 of the capacitive touch sensor, although the touch sensor 20 may further include an electrode for implementing a pressure-sensitive function in addition to these electrodes.

In the present embodiment, the present disclosure is applied to the organic EL display device as an example, although may be applied to any flat panel display device, including a liquid crystal display device, other self-luminous display devices, and an electronic paper display device having an electrophoretic device. Further, needless to say, the present disclosure may be applied to medium size to large size devices without any limitation.

In the above embodiment, the organic EL panel is taken as a most effective example. In this regard, the present invention disposes the touch electrode 22 and the antenna wire 27 in the same layer so as to improve the communication accuracy by the antenna 25 as shown in FIG. 3, and display panels in other types, such as a liquid crystal panel, may also be used.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a display panel providing a display function;
a touch electrode included in a touch sensor that is formed in a layer disposed on a display surface side of the display panel; and
an antenna wire for a near field communication function formed in a same layer as the touch electrode.

2. The display device according to claim 1, wherein
the display panel is implemented by means of organic electroluminescence, and
the touch electrode and the antenna wire are formed on a sealing film covering the organic electroluminescence included in the display panel.

3. The display device according to claim 1, wherein
the antenna wire is formed in a coil having a plurality of turns along a peripheral portion so as to surround a display area of the display panel.

4. The display device according to claim 1, wherein
at least one of a touch wire, which is led out from the touch electrode, or the antenna wire conducts to another layer through a through hole provided in the sealing film so that the touch wire and the antenna wire intersect with each other in different layers.

5. The display device according to claim 4, wherein
the sealing film includes an intermediate layer and outer layers, the intermediate layer being put between the outer layers,
the outer layers are formed in a way that one of the outer layers is in contact with the other outer layer outside an area in which the outer layers are in contact with the intermediate layer so that the intermediate layer is put between the outer layers, and
the through hole is formed in an area in which the outer layers are in contact with each other.

6. The display device according to claim 4, wherein
a display terminal, a touch terminal, and an antenna terminal are disposed in one of sides of the peripheral portion of the display area of the display panel to constitute a terminal group, the display terminal connecting to a wire led out from the display panel, the touch terminal connecting to the touch wire, the antenna terminal connecting to the antenna wire.

7. The display device according to claim 6, wherein
a first coil terminal and a second coil terminal are disposed adjacent to each other in the terminal group, the first coil terminal being connected to one end of the coiled antenna wire, the second coil terminal being connected to the other end of coiled antenna wire.
